(19) United States
(12) Patent Application Publication
(10) Pub. No.: US 2004/0259316 A1
(43) Pub. Date: Dec. 23, 2004

(54) Fabrication of parallel plate capacitors using BST thin films

(76) Inventors: Baki Acikel, Goleta, CA (US); Troy R. Taylor, Santa Barbara, CA (US); Robert A. York, Santa Barbara, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 10/822,563

(22) Filed: Apr. 8, 2004

Related U.S. Application Data
(63) Continuation-in-part of application No. 10/765,578, filed on Jan. 26, 2004.
Application No. 10/765,578 is a continuation of application No. 10/144,185, filed on May 10, 2002, now Pat. No. 6,683,341.
(60) Provisional application No. 60/337,364, filed on Dec. 5, 2001.
(60) Provisional application No. 60/462,594, filed on Apr. 11, 2003.

(51) Int. Cl. H01L 21/00; H01L 21/20

(52) U.S. Cl. 438/393

(57) ABSTRACT

A parallel-plate capacitor includes a bottom electrode, a BST thin film dielectric region and a top electrode. The capacitor is processed using various orders of processing steps in order to improve the end result.

### CROSS-REFERENCE TO RELATED APPLICATIONS

This application (a) is a continuation-in-part of pending U.S. patent application Ser. No. 10/765,578, “Voltage-Variable Capacitor with Increased Current Conducting Perimeter,” by Robert A. York, filed Jan. 26, 2004; which is a continuation of U.S. patent application Ser. No. 10/144,185, “Voltage-Variable Capacitor with Increased Current Conducting Perimeter,” by Robert A. York, filed May 10, 2002 and issued Jan. 27, 2004 as U.S. Pat. No. 6,683,341; which claims priority under 35 U.S.C. § 119(e) to U.S. Provisional Patent Application Ser. No. 60/337,364, “Ferroelectric Varactor Design,” by Robert A. York, filed Dec. 5, 2001; and (b) claims priority under 35 U.S.C. § 119(e) to U.S. Provisional Patent Application Ser. No. 60/462,594, “Fabrication Of Parallel Plate Capacitors Using BST Thin Films,” by Baki Acikel, Troy Taylor and Robert A. York, filed Apr. 11, 2003. The subject matter of all of the foregoing is incorporated herein by reference in its entirety.

### BACKGROUND OF THE INVENTION

1. Field of the Invention

This invention generally relates to parallel plate capacitors using barium strontium titanate thin films and to processes for fabricating such capacitors.

2. Description of the Related Art

Capacitors are a basic building block for electronic circuits. One design for capacitors is the parallel-plate configuration, in which a dielectric is sandwiched between two electrodes. For example, in a capacitor that is fabricated using semiconductor process technology, one electrode may be a bottom conducting layer, the dielectric may be a ferroelectric thin film deposited over the bottom electrode, and the top electrode may be a metal layer deposited over that. The use of semiconductor process technology allows the fabrication of many capacitors on a single wafer and also permits the integration of capacitors with other circuitry.

Materials in the barium strontium titanate (BST) family are well suited for use in such capacitors. BST generally has a high dielectric constant so that large capacitances can be realized in a relatively small area. Furthermore, BST has a permittivity that depends on the applied electric field. As a result, voltage-variable capacitors (varactors) can be produced, with the added flexibility that their capacitance can be tuned by changing a bias voltage across the capacitor. In addition, the bias voltage typically can be applied in either direction across a BST capacitor since the film permittivity is generally symmetric about zero bias. That is, BST typically does not exhibit a preferred direction for the electric field. One further advantage is that the electrical currents that flow through BST capacitors are relatively small compared to other types of semiconductor varactors.

However, BST processing can be demanding. High temperatures can be required to grow BST thin films. This can limit what other materials may be used. For example, if low melting point materials are deposited before the BST thin films are grown, the high temperature growth process can melt or otherwise degrade the materials. In addition, the BST itself can be damaged or its material properties degraded by subsequent processing steps. As a result, it would be beneficial to develop fabrication techniques that avoid or reduce these unwanted effects.

### SUMMARY OF THE INVENTION

The present invention overcomes the limitations of the related art by providing various methods for fabricating BST parallel plate capacitors. In some aspects of the invention, the order of process steps is selected so that the interface between the BST material and the capacitor electrodes is formed early on, before the BST material is degraded by exposure to other processing steps.

In one aspect of the invention, a bottom electrode for the capacitor is formed, supported by a substrate. This includes forming the lateral shape of the bottom electrode. A BST thin film dielectric region is formed over the bottom electrode. BST material is produced (e.g., by standard BST growth techniques) over the bottom electrode only after the lateral shape of the bottom electrode is formed. This is beneficial because it reduces the amount of processing to which the BST material is exposed. If the BST material were produced before the lateral shape of the bottom electrode was formed, the BST material would be exposed to the process used to form the shape of the bottom electrode. A top electrode is also formed over the BST thin film dielectric region.

In another aspect of the invention, a bottom electrode is formed supported by a substrate and a BST thin film dielectric region is formed over the bottom electrode. This includes producing BST thin film material over the bottom electrode. Top electrode material is formed over the BST thin film material immediately after the BST thin film material is produced. The lateral shape of the BST thin film dielectric region is formed only after producing the top electrode material. One advantage of this approach is that the interface between the BST material and the top electrode is formed earlier in the processing. As a result, the BST material is exposed to fewer other processing steps since the top electrode material protects it. The BST material degrades less, also resulting in a higher quality interface between the BST thin film and the top electrode.

In other aspects of the invention, a passivation structure is also formed over the BST thin film dielectric region. The passivation material (e.g., silicon nitride) is produced over the BST material only after the top electrode material is produced. The BST material can also be annealed, which preferably also occurs after the top electrode material is produced.

In one particular design, platinum is used for the bottom electrode, BST thin film for the dielectric region, and platinum for the top electrode. The platinum bottom electrode is formed by a liftoff process. A BST thin film is then grown over the bottom electrode but its lateral shape is not formed. The platinum top electrode is also formed by liftoff. The lateral shape of the BST thin film dielectric region is then formed. A silicon nitride passivation layer is formed over the BST thin film dielectric region and the BST thin film is annealed. This processing order forms the interfaces between the BST thin film and the platinum electrodes before the BST thin film has been exposed to much processing, resulting in high quality interfaces.

### BRIEF DESCRIPTION OF THE DRAWING

The invention has other advantages and features which will be more readily apparent from the following detailed description of the invention and the appended claims, when taken in conjunction with the accompanying drawing, in which:

FIGS. 1A-1D are top view and cross-sectional view pairs, illustrating a fabrication process for BST parallel plate capacitors.

FIGS. 2A-2E are top view and cross-sectional view pairs, illustrating another fabrication process for BST parallel plate capacitors.

FIGS. 3A-3E are top view and cross-sectional view pairs, illustrating yet another fabrication process for BST parallel plate capacitors.

### DETAILED DESCRIPTION OF THE PREFERRED EMBODIMENTS

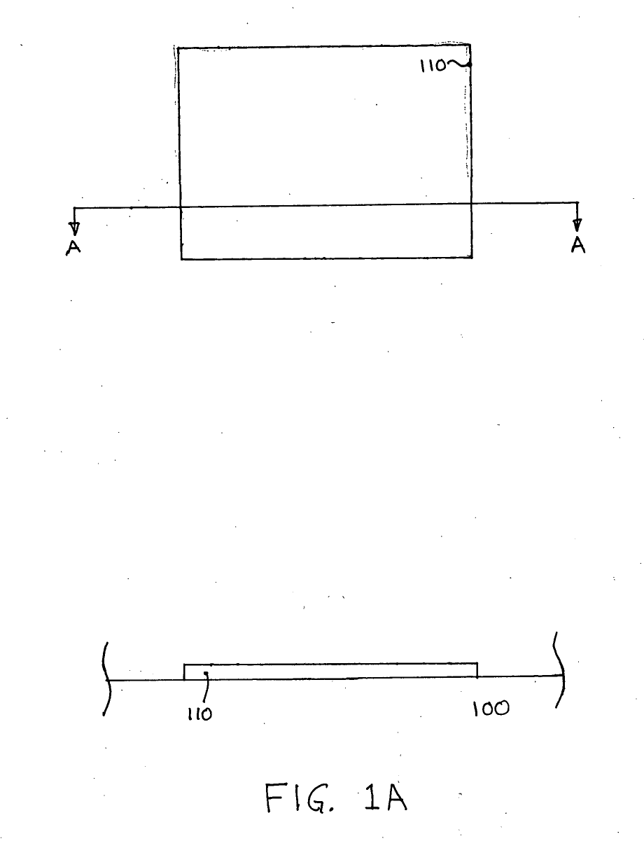

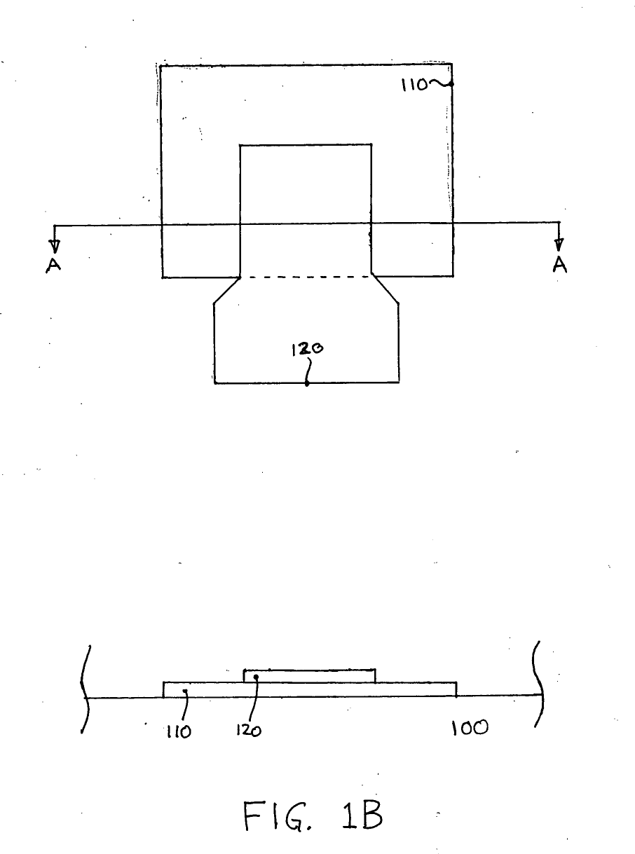

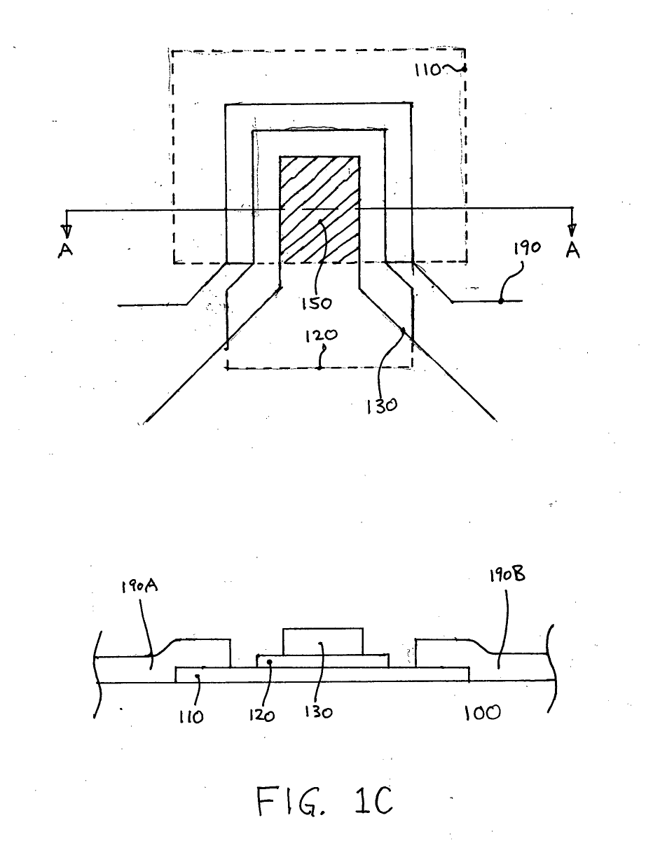

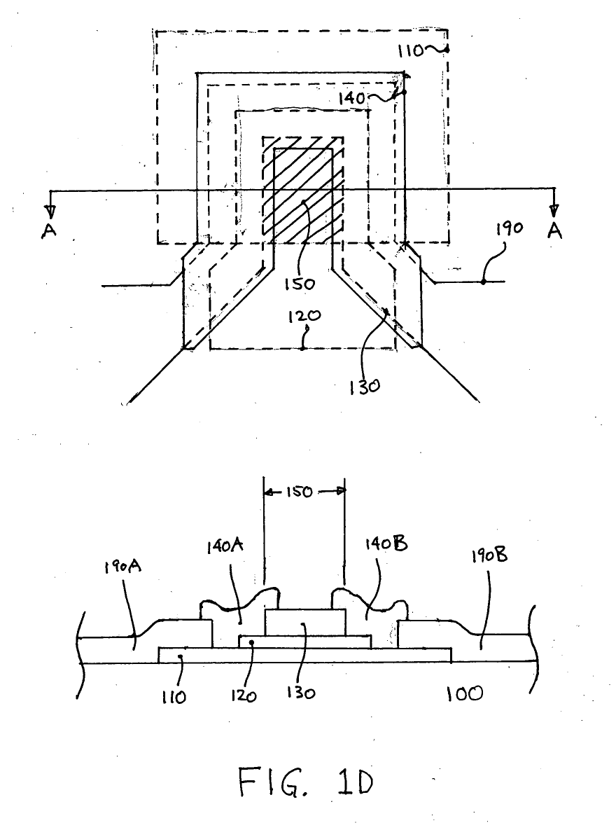

FIGS. 1, 2 and 3 illustrate three different examples of BST (barium strontium titanate) parallel plate capacitors that are fabricated according to the invention. Each individual figure shows a different phase of fabrication and each sequence of figures shows the overall fabrication process. Each figure shows both a top view and a corresponding cross-sectional view A-A of the capacitor during fabrication. The fabricated capacitor is shown in the last figure of each sequence. The capacitor is integrated on a substrate 100 and includes a bottom electrode 110, a top electrode 130 and a BST thin film dielectric region 120 sandwiched between the top electrode and the bottom electrode. The active region 150 of the capacitor is defined by the overlap between the top electrode 130, the dielectric region 120 and the bottom electrode 110.

The capacitors in FIGS. 1-3 are drawn with specific shapes for the electrodes 110 and 130, dielectric region 120 and active region 150. However, this is not meant as a limitation. The figures are used to illustrate certain fabrication techniques and these techniques can be applied to parallel plate capacitors of different shapes. Furthermore, the figures show the most relevant structures 110, 120, 130 of the capacitor, but this does not imply that other structures or layers do not exist. For example, additional layers located between those shown may be used for various purposes according to conventional techniques. Examples include layers to increase adhesion, to provide a diffusion barrier, or to improve the Schottky barrier height. As another example, the bottom electrode 110 is always shown as supported directly by the substrate 100. This is for convenience, and other layers or structures can be located between the bottom electrode 110 and the substrate 100. In addition, each layer 110, 120, 130 can also include one or more types of materials, although they are shown and will be described as single layers of material in the following examples.

In some applications, the BST capacitor has a fixed capacitance. One advantage of using BST as the dielectric material is that BST thin-film materials have a high intrinsic capacitance density. As a result, capacitors of a given capacitance can be realized by small active regions compared to other technologies. In other applications, the capacitance of the BST capacitor can be voltage-variable (i.e., a varactor). The BST dielectric region 120 can be voltage-variable since the BST dielectric material has a field-dependent electrical permittivity. Thus, the capacitance of the varactor can be changed by changing the voltage applied across the BST dielectric region 120. For example, changing the voltage applied across the two electrodes 110,130 changes the electric field within the dielectric region 120. This, in turn, changes the dielectric constant of the BST material, thus changing the capacitance of the varactor. The BST thin film dielectric region 120 preferably exhibits a field-dependent permittivity in a (non-hysteretic) paraelectric state over a useful temperature range (e.g., −30 C. to +90C.). The comments in this document generally apply to both the fixed capacitance and the variable capacitance case.

Examples of suitable BST thin film materials for dielectric region 120 include barium titanate, strontium titanate, and composites of the two. For convenience, the term “BST” shall be used throughout to refer to all of these materials even though, strictly speaking, barium titanate does not contain strontium and strontium titanate does not contain barium. The terms “barium titanate”, “strontium titanate”, and “barium strontium titanate” shall be used to refer to the specific materials. This is strictly for convenience, in order to avoid having to repeat the phrase “barium titanate, strontium titanate and/or barium strontium titanate” throughout. The BST materials can also include small concentrations of one or more dopants to modify certain properties.

To reduce costs, temperature resistant, inexpensive insulating substrates 100 are usually preferred, including but not limited to high-resistivity silicon (HR Si), crystalline sapphire (Al₂O₃), aluminum nitride (AlN), quartz and glass. These substrates are preferably polished for low surface roughness for compatibility with growth of smooth ferroelectric films with high breakdown fields. This approach results in low-cost, small size, reliable components which are suitable for mass production and for integration with other circuit elements.

BST thin-film capacitors (including varactors) can be used in a variety of applications such as radio-frequency (RF) or wireless electronics, voltage-controlled oscillators, impedance matching networks, tunable filters, and numerous other applications. As one example application, BST varactors can be used in RC tuning circuits for RF applications, such as mobile phones. While specific numbers will vary by application, 2:1 capacitance variations and capacitances in the range of 0.01 pF to 10 nF are not unheard of. Similarly, DC control voltages may be in the range of −100 to +100 volts, depending on the BST film thickness and the specific application. The varactors preferably are operated at voltages that are less than half their intrinsic breakdown voltage.

A thin-film capacitor is attractive because it can be easily integrated alongside other active and passive electrical components on many different host substrates, including semiconductors (such as silicon, gallium arsenide, silicon carbide, gallium nitride, etc.) and insulators (such as glass, quartz, sapphire, etc.). However, processing steps for BST thin films can require conditions that limit the choice of materials for the electrodes and other structures. For example, the growth of BST thin films can require high temperature processing that limits electrode materials (at least for the materials that are present when the high temperature processing occurs) to those that have high melting points and that also do not oxidize easily. Examples of such materials include platinum and other refractory metals such as palladium and tungsten, but generally exclude commonly used conductors such as gold, copper and aluminum. Other suitable materials can include other noble metals and conductive oxides. Unfortunately, materials such as platinum typically have higher resistivity and can also be quite expensive. In some cases, the electrode can be shaped to reduce resistance. For example, an electrode that is narrow in the active region can open up into a wide area that has significantly less resistance compared to the narrow portion. Alternately, the electrodes can contact other layers that have better conductivity, for example thick gold layers that are formed after the BST processing steps are completed. Generally speaking, the fabrication process for BST capacitors, including even the order of processing steps, can affect the overall design, cost and performance of the capacitor.

FIGS. 1A-1D are pairs of top view and cross-sectional view, illustrating one fabrication process for a BST parallel plate capacitor. Referring first to the finished capacitor shown in FIG. 1D, the bottom electrode 110 contacts a conducting layer 190 (shown as 190A-190B in the cross section). The crosshatched active region 150 is defined by the lateral overlap of the bottom electrode 110, the BST thin film dielectric region 120 and the top electrode 130. The bottom electrode 110 is platinum in this example in order to withstand the high temperatures used during growth of the BST thin film 120. The conducting layer 190 is a thick metal layer, gold in this example, that provides electrical connection with reduced resistance to the bottom electrode 110. The top electrode 130 can be formed from the same thick metal layer as layer 190 or a separately deposited layer. In this example, it is the same gold layer. A passivation structure 140 covers the BST dielectric region 120. Here, the passivation structure 140 is silicon nitride that is sputtered onto the device, although other materials including oxides (e.g., Al₂O₃ and SiO₂) can be used.

In the top view, visible structures are shown by solid lines and hidden structures by dashed lines. The lead line for the reference numeral (except for 150) contacts the border for that structure and the reference numeral is placed in the interior of the structure. For example, the lead line for 110 (bottom electrode) contacts a rectangular border and the reference numeral is located on the inside of the rectangle. Therefore, the bottom electrode 100 is rectangular in shape. If the reference numeral 110 were located on the outside of the rectangle, then the lateral shape of the structure would be a solid sheet with a rectangular hole in it. The dashed border means the bottom electrode 110 is hidden in this view. That is, it is located under other structures.

In the top view of FIG. 1D, the passivation structure 140 is fully visible. The top electrode 130 and the conducting layer 190 are also fully or mostly visible. The passivation structure 140 slightly overlaps the top electrode 130, and these two structures together cover the BST thin film dielectric region 120. The dielectric region 120 is an eight-sided shape that is shown as dashed in the top view since it is hidden by the top electrode 130 and passivation structure 140. Five of the eight sides are obscured by the passivation structure 140, two of the eight sides are obscured by both the passivation structure 140 and the top electrode 130, and one side is obscured by top electrode 130. The bottom electrode 110 is rectangular in shape and is entirely hidden in the top view. The overall structure of the capacitor will be more apparent when the fabrication process is described.

Turning now to fabrication, the bottom electrode 110 is formed on substrate 100. This includes forming the lateral shape of the electrode 110, as shown in FIG. 1A. In one approach, a layer of material for the bottom electrode is formed over the substrate 100. Selected lateral portions of the bottom electrode layer are then removed, for example by etching, thus forming the lateral shape of the bottom electrode 110. In an alternate approach, a lift off process is used. A lift off mask that defines the lateral shape of the bottom electrode 110 is formed over the substrate. A layer of bottom electrode material is deposited over the lift off mask. Removing the lift off mask also removes the bottom electrode material in certain areas, thus forming the lateral shape of the bottom electrode 110.

In one particular embodiment of this design, the substrate 100 is sapphire and the bottom electrode 110 is a thin layer of platinum. Platinum is selected for compatibility with the BST processing. A thin layer is preferred because it does not become as rough during the subsequent BST high temperature growth steps, resulting in better BST film and interface quality. A lift off approach is used because it can produce thicker bottom electrodes 110 and results in cleaner surfaces. It also avoids having to etch platinum. Specifically, a patterned photoresist layer is deposited over the substrate 100. A thin layer of titanium is evaporated on top of this to function as an adhesion layer, and platinum is deposited on top of the titanium. Removing the photoresist lift off mask leaves the platinum bottom electrode 110 shown in FIG. 1A. Other patterning techniques can be used, for example etching the platinum layer to form the bottom electrode 110.

Referring to FIG. 1B, the BST thin film dielectric region 120 is formed over the bottom electrode 110. In this example, a BST thin film is grown on top of the platinum electrode 110. The film is patterned and the thin film located in unwanted regions is etched away, resulting in the dielectric region 120 shown in FIG. 1B. Conventional BST growth and patterning techniques are used. The dielectric region 120 overlaps the bottom electrode 110, as shown in FIG. 1B.

Note that BST material is produced over the bottom electrode 110 only after the lateral shape of the platinum electrode 110 is formed. This is beneficial because it reduces the amount of processing to which the BST material is exposed. Exposure to less processing generally results in higher quality material (i.e., less degradation of the BST material properties). For example, the bottom electrode 110 and BST dielectric region 120 could have been formed by depositing a platinum layer, depositing a BST thin film on top of that, and then etching both layers to form the lateral shapes. However, in this approach, the BST layer is already on the substrate when the platinum layer is etched and may be exposed to the platinum etch process. This can degrade the BST quality and also degrade the quality of the interface between the BST thin film 120 and the top electrode 130, which has not yet been formed. In the approach shown in FIG. 1, the BST material is deposited only after the lateral shape of the platinum electrode 110 has already been formed, thus avoiding exposure to this extra step.

Referring to FIG. 1C, a top electrode 130 is formed over the BST thin film dielectric region 120. In this example, a gold layer is deposited and patterned to form both the top electrode 130 and the conducting layer 190 shown in FIG. 1C. The gold conducting layer 190 overlaps with the platinum bottom electrode 110, thus providing a low resistance electrical path to the platinum electrode 110. It is advantageous to place the gold conducting layer 190 in close proximity to the active region 150, in order to reduce the overall resistance resulting from the platinum electrode 110. In an alternate embodiment, platinum is used to form the top electrode 130. One advantage of platinum is that it forms a high quality interface with the BST thin film. Another advantage is that it can better withstand the subsequent BST annealing process.

The passivation structure 140 is also formed over the BST thin film dielectric region 120, as shown in FIG. 1D. The material for passivation structure 140 is produced over the BST material only after the interface between the top electrode 130 and the BST material 120 has been formed. In this example, the silicon nitride material for the passivation structure 140 is deposited after the gold for top electrode 130. One advantage of this approach is that the material for the top electrode 130 is deposited earlier in the processing. As a result, the BST material located under the top electrode material is exposed to fewer processing steps and will degrade less. For example, if reactive ion etching (RIE) is used to form the passivation structure 140, the top electrode 130 protects the underlying BST material from RIE damage, resulting in a better interface between the BST material and the top electrode. Generally speaking, it is desirable to form the top electrode-BST interface earlier in the processing so as to form a good quality interface.

In one approach, the BST thin film is grown and patterned to form the BST thin film dielectric region 120. Gold for the top electrode 130 is then deposited and patterned. For example, a wet etch that attacks gold but not BST can be used to form the lateral shape of the top electrode 130. Examples of etchants include iodine-based gold etchants. Then, material for the passivation structure 140 is deposited. Compare this to a process in which the passivation structure 140 is formed before the top electrode 130. In this process, the passivation material (silicon nitride in this example) is deposited over the BST material and patterned. Gold for the top electrode 130 is then deposited. Note that the BST material (including the material which eventually forms the interface with the top electrode 130) is exposed to the entire passivation process before the gold material is deposited.

It is also desirable to produce the passivation structure 140 early in processing in order to protect other lateral areas of the BST dielectric region 120. Preferably, material for the passivation layer 140 is produced after processing steps for forming the top electrode 130 but before processing steps for forming any other structure in the capacitor. One advantage of this approach is that the passivation structure 140 protects the underlying BST material in later processing steps. As a result, earlier formation of the passivation structure 140 means greater protection for the BST dielectric region 120.

After BST processing is completed, standard annealing techniques typically are used to improve the quality of the BST materials, for example by repairing damage which may occur during BST processing steps. Annealing can also improve the quality of the interface between the BST material and the electrodes.

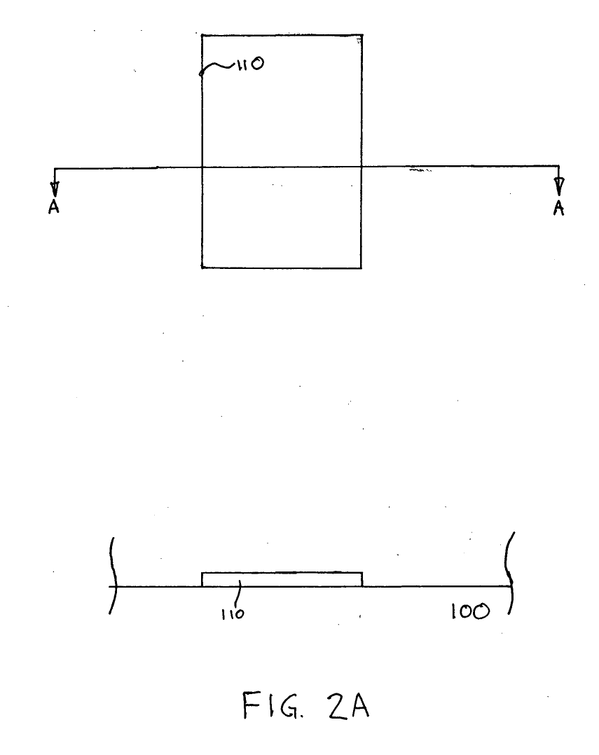

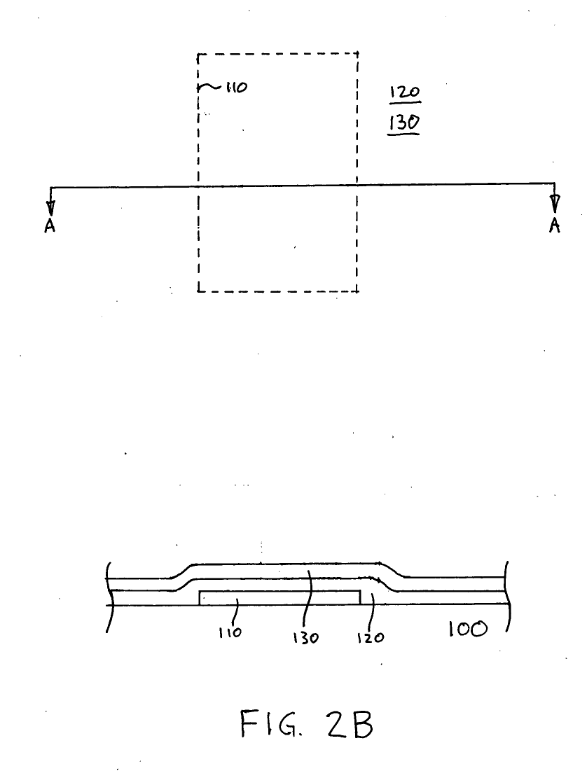

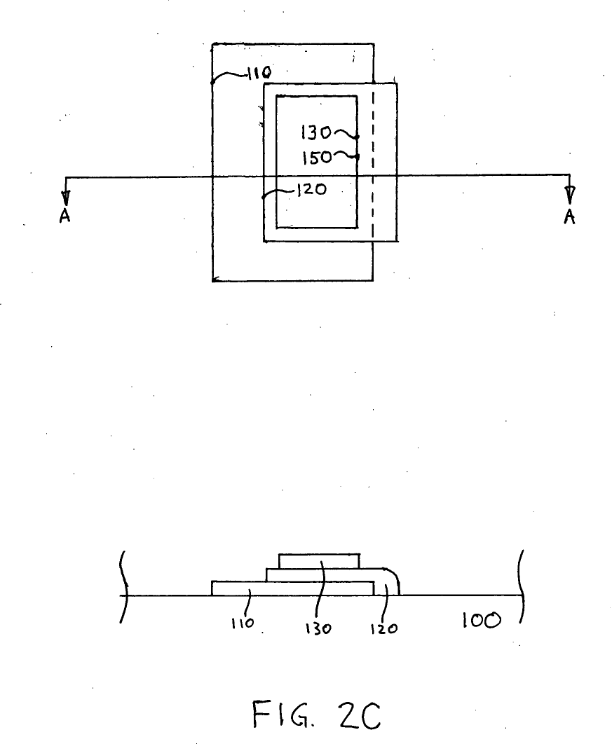

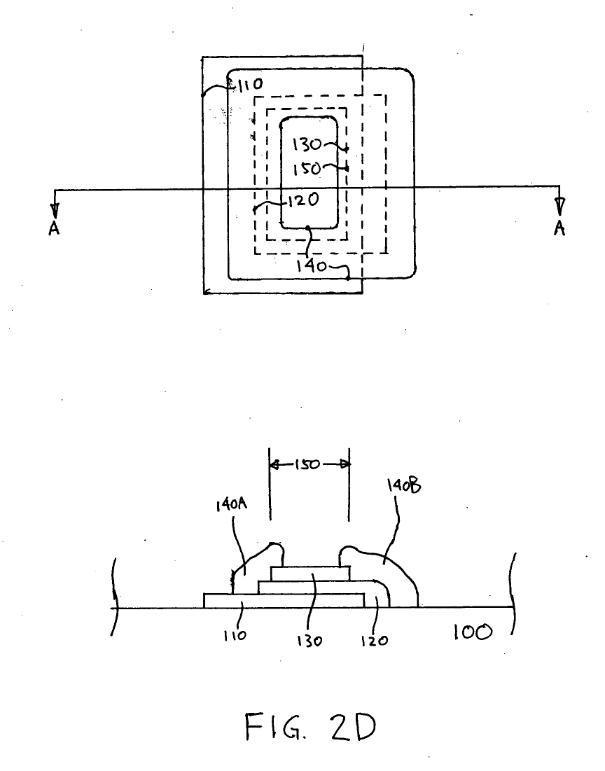

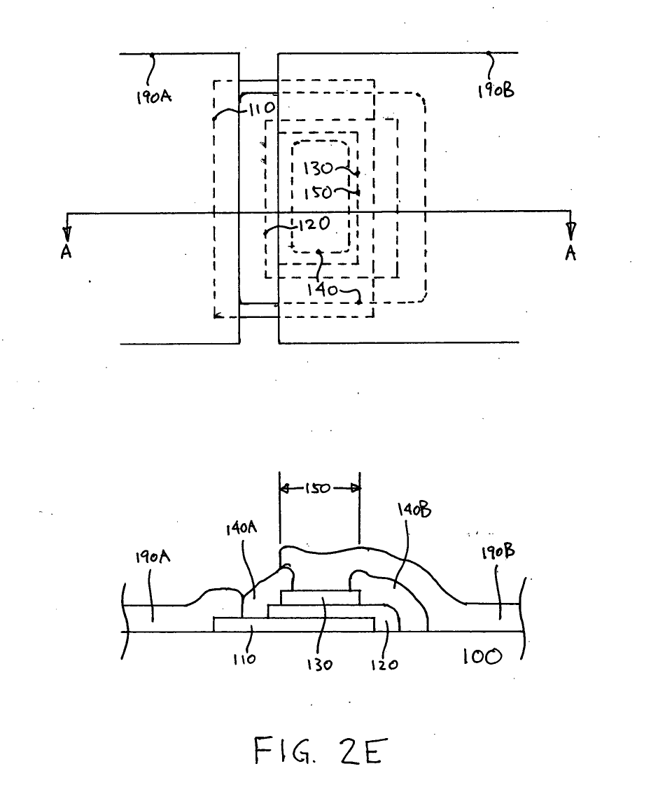

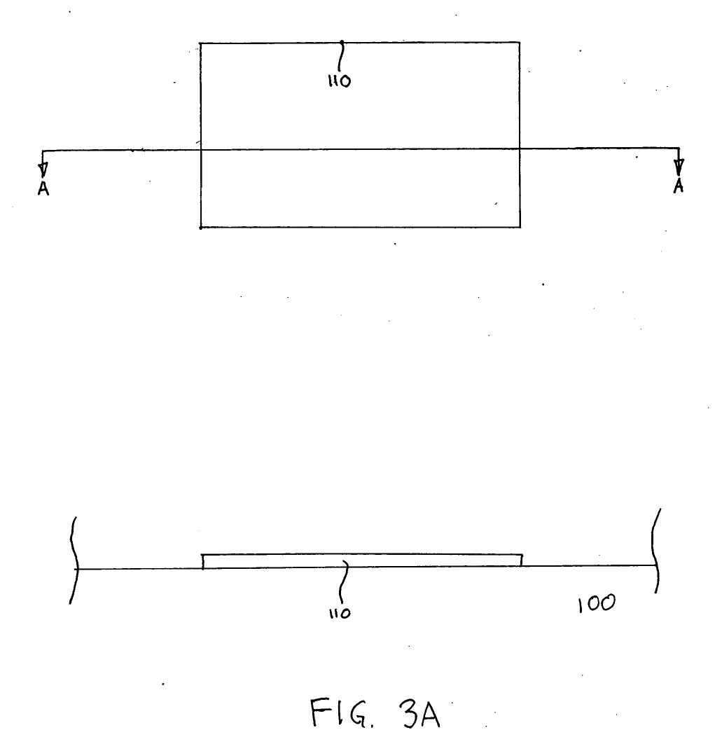

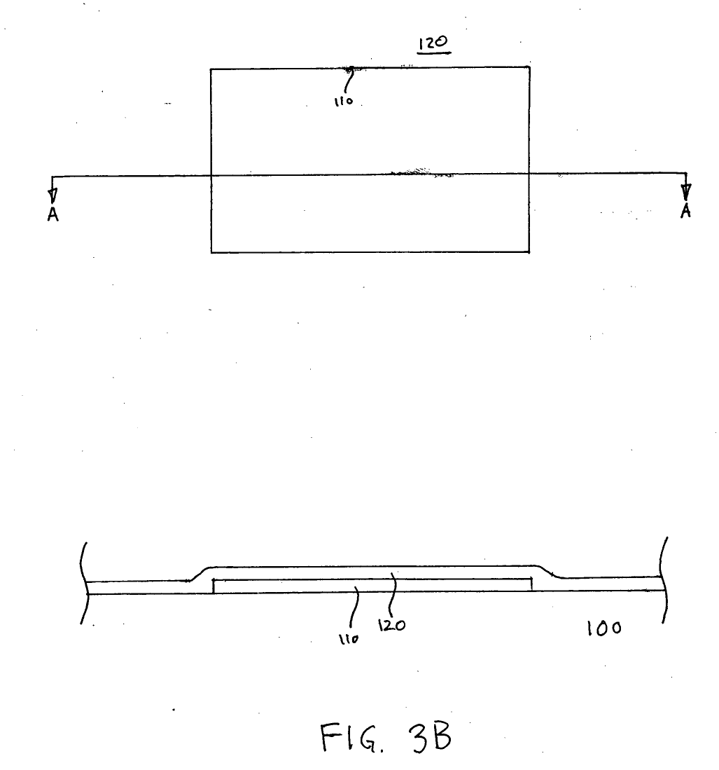

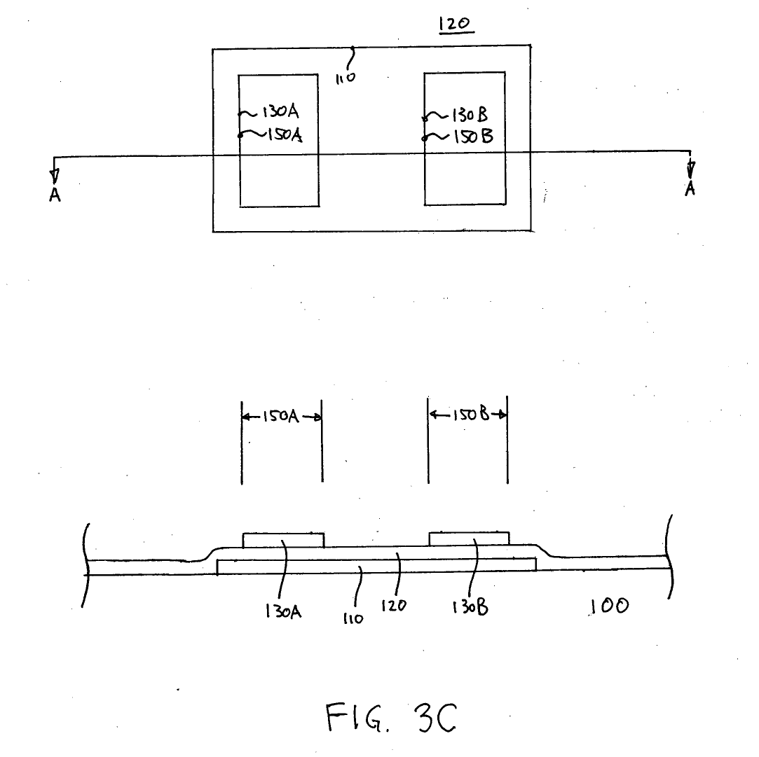

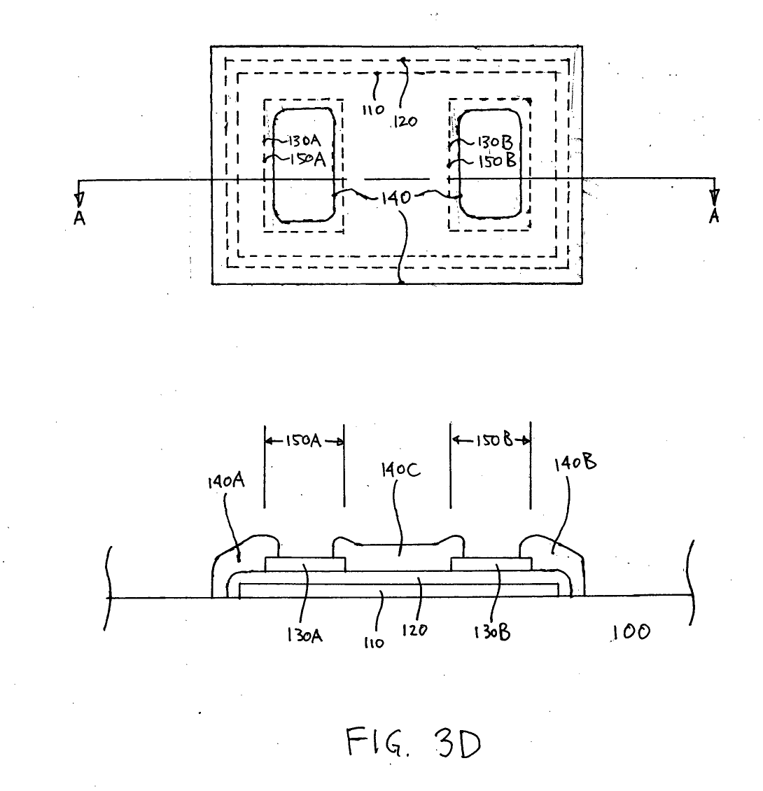

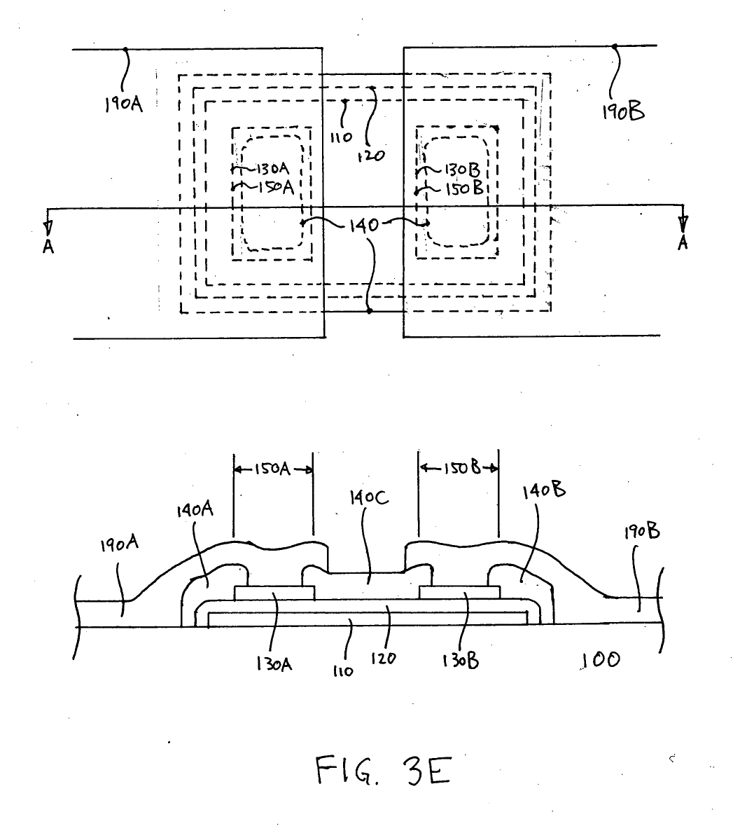

FIGS. 2 and 3 illustrate additional variations of the fabrication process, using specific designs as examples. In FIG. 2, there is one capacitor, but as shown in the cross section of FIG. 2E, the electrical contact 190A to the bottom electrode 110 extends to one side and the electrical contact 190B to the top electrode 130 extends to the other side. This is a different geometrical layout than the one shown in FIG. 1.

In FIG. 3, there are two capacitors, as shown by the two active areas 150A and 150B. A platinum layer serves as a common bottom electrode 110 for both capacitors, thus coupling the capacitors in series. For ease of fabrication, a single BST thin film serves as the dielectric region 120 for both capacitors. However, there are two separate top electrodes 130A,130B, which serve as the two terminals to the series-coupled capacitors. Alternately, the two capacitors can be coupled in parallel by using the bottom electrode 110 as one terminal and by coupling the two top electrodes 130A,B together as the other terminal.

Referring to FIGS. 2E and 3E, another difference compared to FIG. 1 is that the top electrode 130 is deposited and then followed by a separately deposited conducting layer 190. In FIG. 1, the top electrode 130 is not a separate layer from the remainder of the electrical contact. FIGS. 2 and 3 also use a different order of processing steps to form the BST thin film dielectric region 120 and top electrode 130, as will be further discussed below. In FIG. 3, the bottom electrode 110 and BST thin film dielectric region 120 are the same size and shape.

In more detail, both FIGS. 2A and 3A show the capacitor after the bottom electrode 110 is formed on substrate 100. This process is analogous to what is shown in FIG. 1A.

Referring to FIGS. 2B-2C, the BST thin film dielectric region 120 and top electrode 130 are formed, but using a different order for process steps than shown in FIGS. 1B-1C. In this example, as shown in FIG. 2B, a BST thin film 120 is grown over the platinum bottom electrode 110 but the lateral shape of the dielectric region (e.g., see 120 in FIG. 2E) is not formed. A platinum layer 130 for the top electrode is deposited over the BST thin film 120. The result is shown in FIG. 2B. The lateral shapes for the BST thin film dielectric region 120 and top electrode 130 are then formed. This can be done in a common process if the BST thin film dielectric region 120 and top electrode 130 have the same shape. Alternately, separate processes can be used, one to form the lateral shape of the top electrode 130 and another for the dielectric region 120. In one approach, a selective etch is used to form the lateral shape of the top electrode 130. This is followed by an etch that forms the lateral shape of the BST dielectric region 120. The result is shown in FIG. 2C.

One advantage of this approach is that the two BST-electrode interfaces (i.e., the interface between bottom electrode 110 and BST thin film 120, and the interface between the BST thin film 120 and top electrode 130) are formed before the BST thin film is exposed to very much processing, resulting in higher quality interfaces. Another advantage is that the top electrode material can be deposited immediately (i.e., as the next significant processing step(s)) after the BST thin film growth. For platinum top electrodes, both depositions can occur in the same processing chamber under high vacuum conditions at elevated temperatures.

In FIGS. 3B-3C, the BST thin film dielectric region 120 and top electrode 130 are formed in yet a different manner. Specifically, BST material is grown over bottom electrode 110 but the lateral shape of the dielectric region is not formed. Then, the platinum top electrode 130 is formed using a lift off process, as shown in FIG. 3C. The lateral shape of the BST thin film 120 is then formed. Again, in this approach, the two BST-electrode interfaces are formed before the BST thin film is exposed to very much processing.

Referring to FIGS. 2D and 3D, the passivation structure 140 is formed over the BST thin film dielectric region 120. In FIG. 2D, the passivation structure 140 has an annular lateral shape, as indicated by the lead line from reference numeral 140 contacting two separate borders. The center hole in the passivation structure 140 gives access to the top electrode 130, as can be seen from the cross section. In FIG. 3D, the passivation structure 140 has two holes, one for each top electrode 130A,130B. As in FIG. 1, the BST material is covered by a combination of the top electrode 130 and the passivation structure 140.

Referring to FIGS. 2E and 3E, the conducting layer 190 is formed. In FIG. 2E, the conducting layers 190A,B make contact to the top electrode 130 and bottom electrode 110, respectively. In FIG. 3E, the conducting layers 190A,B contact the two top electrodes 130A,B. In FIG. 2E, an additional capacitor is formed by the conducting layer 190B as one electrode, the bottom electrode 110 as the other electrode and the BST thin film 120 and passivation structure 140B as the dielectric. This capacitor is in parallel with the BST capacitor defined by active area 150 and adds to its capacitance. As a result, it is usually desirable for the passivation material to have a dielectric constant that is significantly less than that of the BST thin film so that the active region 150 dominates the overall capacitance.

Although the invention has been described in considerable detail with reference to certain preferred embodiments thereof, other embodiments will be apparent. For example, fabrication processes are not required to use all of the processing techniques discussed above. Various embodiments can use only some of the techniques. Similarly, techniques illustrated in one sequence of figures can be combined with techniques illustrated in another sequence of figures. For example, the approach shown in FIGS. 2B-2C for forming the BST thin film dielectric region 120 and top electrode 130 can also be used in the fabrication processes shown in FIGS. 1 and 3. As another example, a particular step may be described as using a selective wet etch to form the lateral shape of a structure. In alternate embodiments, a lift off process, dry etch or other standard processes may be used instead.

The specific geometries and shapes shown are also not required. For example, the shapes of the top and bottom electrodes can be reversed, essentially turning the capacitor design upside down on the substrate. As another example, the structures can be curved in shape, for example circular, semicircular or serpentine. There can be different amounts of overlap between the structures. The passivation structure 140 and top electrode 130 are not required to cover the entire BST material 120 (although usually it is desirable to do so). As a final example, the principles described above apply also to arrays of capacitors. Therefore, the scope of the appended claims should not be limited to the description of the preferred embodiments contained herein.

What is claimed is:

1. A method for fabricating a BST parallel plate capacitor comprising:
forming a bottom electrode supported by a substrate, including forming a lateral shape of the bottom electrode;
forming a BST thin film dielectric region over the bottom electrode, including producing BST material over the bottom electrode only after the lateral shape of the bottom electrode is formed; and
forming a top electrode over the BST thin film dielectric region.

2. The method of claim 1 wherein the step of forming a bottom electrode supported by a substrate comprises:
forming a lift off mask over the substrate, the lift off mask defining the lateral shape of the bottom electrode;
depositing a layer of bottom electrode material over the lift off mask; and
removing the lift off mask, thereby forming the lateral shape of the bottom electrode.

3. The method of claim 2 wherein:
the step of forming a lift off mask over the substrate comprises depositing a photoresist lift off mask over the substrate; and
the step of depositing a layer of bottom electrode material over the lift off mask comprises depositing a platinum layer over the photoresist lift off mask.

4. The method of claim 1 wherein the step of forming a bottom electrode supported by a substrate comprises:
forming a layer of bottom electrode material over the substrate; and
removing selected lateral portions of the bottom electrode material, thereby forming the lateral shape of the bottom electrode.

5. The method of claim 4 wherein:
the step of forming a layer of bottom electrode material over the substrate comprises depositing a platinum layer over the substrate; and
the step of removing selected lateral portions of the bottom electrode material comprises etching away selected lateral portions of the platinum layer.

6. The method of claim 1 wherein the bottom electrode is a platinum bottom electrode.

7. The method of claim 6 further comprising:
forming a titanium adhesion layer located between the substrate and the platinum bottom electrode.

8. The method of claim 1 wherein the bottom electrode consists essentially of a noble metal.

9. The method of claim 1 wherein the bottom electrode consists essentially of a conductive oxide.

10. A method for fabricating a BST parallel plate capacitor comprising:
forming a bottom electrode supported by a substrate;
forming a BST thin film dielectric region over the bottom electrode, including producing BST thin film material over the bottom electrode; and
forming a top electrode over the BST thin film dielectric region, including producing top electrode material over the BST thin film material immediately after producing the BST thin film material, wherein a lateral shape of the BST thin film dielectric region is formed only after producing the top electrode material over the BST thin film material.

11. The method of claim 10 wherein the step of forming a top electrode over the BST thin film dielectric region comprises, immediately after producing the BST thin film material and before forming a lateral shape of the BST thin film dielectric region:
forming a lift off mask over the BST thin film material;
depositing a layer of top electrode material over the lift off mask; and
removing the lift off mask, thereby forming the lateral shape of the top electrode.

12. The method of claim 11 wherein:
the step of forming a lift off mask over the BST thin film material comprises depositing a photoresist lift off mask over the BST thin film material; and
the step of depositing a layer of top electrode material over the lift off mask comprises depositing a platinum layer over the photoresist lift off mask.

13. The method of claim 10 wherein the step of forming a top electrode over the BST thin film dielectric region comprises, immediately after producing the BST thin film material and before forming a lateral shape of the BST thin film dielectric region:
forming a layer of top electrode material over the BST thin film material; and
removing selected lateral portions of the top electrode material, thereby forming the lateral shape of the top electrode.

14. The method of claim 13 wherein:
the step of forming a layer of top electrode material over the BST thin film material comprises depositing a platinum layer over the BST thin film material; and
the step of removing selected lateral portions of the top electrode material comprises etching away selected lateral portions of the platinum layer.

15. The method of claim 13 wherein the step of forming a layer of top electrode material over the BST thin film material comprises:
depositing a platinum layer over the BST thin film material, wherein deposition of the platinum layer occurs in a same processing chamber as production of the BST thin film material, and without interim removal of the BST parallel plate capacitor from the processing chamber.

16. The method of claim 10 wherein the top electrode is a platinum top electrode.

17. The method of claim 10 further comprising:
forming a passivation structure over the BST thin film dielectric region, including producing passivation material over the BST material only after the top electrode material is produced over the BST material.

18. The method of claim 17 wherein the passivation structure consists essentially of Al₂O₃ or SiO₂.

19. The method of claim 17 wherein the passivation structure consists essentially of a silicon nitride.

20. The method of claim 17 wherein producing passivation material over the BST material occurs immediately after the top electrode is formed.

21. The method of claim 10 further comprising:
annealing the BST thin film dielectric region only after the top electrode material is produced over the BST material.

22. A method for fabricating a BST parallel plate capacitor comprising:
forming a platinum bottom electrode supported by a substrate, including forming a lateral shape of the platinum bottom electrode;
forming a BST thin film dielectric region over the platinum bottom electrode, including producing BST material over the platinum bottom electrode only after the lateral shape of the platinum bottom electrode is formed; and
forming a top electrode over the BST thin film dielectric region, including producing top electrode material over the BST material either immediately after the BST material is produced or immediately after the lateral shape of the BST thin film dielectric region is formed.

23. The method of claim 22 wherein:
the top electrode material is produced over the BST material immediately after the BST material is produced; and
a lateral shape of the top electrode is formed before a lateral shape of the BST thin film dielectric region is formed.

24. The method of claim 22 wherein the step of forming a platinum bottom electrode comprises using a lift off process to form the platinum bottom electrode.

25. The method of claim 22 wherein the step of forming a top electrode over the BST thin film dielectric region comprises using a lift off process to form a platinum top electrode.

26. The method of claim 22 wherein the step of forming a top electrode over the BST thin film dielectric region comprises using deposit and etch processes to form a platinum top electrode.

27. The method of claim 22 wherein the top electrode is a gold top electrode.

28. The method of claim 22 further comprising:
forming a passivation structure over the BST thin film dielectric region, including producing passivation material over the BST material only after the top electrode material is produced over the BST material.

29. The method of claim 22 further comprising:
annealing the BST thin film dielectric region only after forming the passivation structure.

30. The method of claim 22 wherein:
the step of forming a platinum bottom electrode comprises using a lift off process to form the platinum bottom electrode;
the top electrode material comprises platinum, and the top electrode is formed using a lift off process immediately after the BST material is produced and before a lateral shape of the BST thin film dielectric region is formed;
wherein the method further comprises:
forming a passivation structure over the BST thin film dielectric region, including producing passivation material over the BST material only after the top electrode material is produced over the BST material; and
annealing the BST thin film dielectric region only after forming the passivation structure.
